(19) United States
(12) Patent Application Publication
(10) Pub. No.: US 2013/0052802 A1
(43) Pub. Date: Feb. 28, 2013

(54) MOLD THERMOPHYSICAL PROPERTIES FOR THICKNESS UNIFORMITY OPTIMIZATION OF EXOCAST SHEET

(71) Applicants: Glen Bennett Cook, Elmira, NY (US); Prantik Mazumder, Ithaca, NY (US); Balram Suman, Katy, TX (US)

(72) Inventors: Glen Bennett Cook, Elmira, NY (US); Prantik Mazumder, Ithaca, NY (US); Balram Suman, Katy, TX (US)

(21) Appl. No.: 13/214,366

(22) Filed: Aug. 22, 2011

(51) Int. Cl. H01L 21/20; B29C 33/38

(52) U.S. Cl. 438/478; 425/275; 257/E21.09

(57) ABSTRACT

The disclosure relates to substrate molds with variable thermal mass. The disclosure relates to substrate molds comprising refractory materials having a leading edge and a trailing edge, wherein the substrate mold has a graded thermal mass comprising a leading edge thermal mass (M_{t(lead)}) and a trailing edge thermal mass (Mₜ₍ₜᵣₐᵢₗ₎), wherein M_{t(lead)} is less than Mₜ₍ₜᵣₐᵢₗ₎. The disclosure also relates to methods of making articles of semiconducting material and methods of minimizing total thickness variation in articles of semiconducting material, said methods comprising using the molds disclosed.

### FIELD OF THE DISCLOSURE

The disclosure relates to substrate molds with variable thermophysical properties, and methods of using the same. In one embodiment, the disclosure relates to substrate molds comprising refractory materials, wherein the substrate mold has a variable thermal mass along the length of the substrate mold. In a further embodiment, the disclosure relates to substrate molds comprising refractory materials having a leading edge and a trailing edge along the length of the substrate mold, wherein the substrate mold has a leading edge thermal mass (M_{t(lead)}) and a trailing edge thermal mass (Mₜ₍ₜᵣₐᵢₗ₎), and wherein M_{T(lead)} is less than Mₜ₍ₜᵣₐᵢₗ₎.

The disclosure also relates to exocasting methods whereby an article of semiconducting material is formed over a surface of a substrate mold having variable thermophysical properties. The disclosure also relates to methods of minimizing the total thickness variation of an article of semiconducting material using a substrate mold having variable thermophysical properties.

### BACKGROUND

Semiconducting materials find uses in many applications. For example, semiconducting materials can be used to manufacture switching elements, such as transistors in electronic devices, e.g., processors, formed on semiconductor wafers. As a further example, semiconducting materials are also used in solar cell manufacturing to convert solar radiation into electrical energy through the photovoltaic effect.

The properties of semiconducting materials may depend on a variety of factors, including crystal structure, the concentration and type of intrinsic defects, and the presence and distribution of dopants and other impurities. Within a semiconducting material, the grain size and grain size distribution, for example, can impact the performance of resulting devices. By way of example, the electrical conductivity and thus the overall efficiency of a semiconductor-based device such as a photovoltaic cell will generally improve with larger and more uniform grains.

For silicon-based photovoltaic cells, the silicon can, for example, be formed as an unsupported sheet or can be supported by forming the silicon on a substrate. Conventional methods for making unsupported and supported articles of semiconducting materials, such as silicon sheets, have several shortcomings.

Methods of making unsupported thin semiconducting material sheets, including silicon sheets, may be slow or wasteful of the semiconducting material feedstock. Unsupported single crystalline semiconducting materials can be produced, for example, using Czochralski or Bridgman processes. However, such bulk methods may disadvantageously result in significant kerf loss when the material is cut into thin sheets or wafers. Additional methods by which unsupported polycrystalline semiconducting materials can be produced include electromagnetic casting and direct net-shape sheet growth methods such as ribbon growth processes. However, these techniques tend to be slow and expensive. Polycrystalline silicon ribbon produced using silicon ribbon growth technologies is typically formed at a rate of only about 1-2 cm/min.

Supported semiconducting material sheets may be made less expensively, but the semiconducting material sheet is limited by the substrate on which it is made, and the substrate has to meet various process and application requirements, which may be conflicting.

Methods for producing unsupported polycrystalline semiconducting materials are disclosed in commonly-owned U.S. Patent Publication No. 2010/0290946, and commonly-owned U.S. Patent Publication No. 2010/0219549, the disclosures of which are hereby incorporated by reference.

The inventors have now discovered novel substrate molds and methods of using the same to produce supported and unsupported articles of semiconducting materials. The methods disclosed herein may facilitate formation of semiconducting materials having desirable attributes, such as uniform total thickness, while reducing material waste and increasing the rate of production.

### SUMMARY

In accordance with the detailed description and various exemplary embodiments described herein, the disclosure relates to substrate molds with variable thermophysical properties, and methods of using the same.

In various exemplary embodiments, the disclosure relates to substrate molds having variable thermal mass along the length of the mold. In at least one embodiment, the substrate mold comprises refractory materials having a leading edge and a trailing edge, wherein the substrate mold comprises a leading edge thermal mass (M_{t(lead)}) and a trailing edge thermal mass (Mₜ₍ₜᵣₐᵢₗ₎), wherein M_{t(lead)} is less than M_{T(trail)}.

In yet further exemplary embodiments, the disclosure relates to methods, including exocasting methods, whereby an article of a semiconducting material is formed over a surface of a substrate mold having variable thermophysical properties. The methods may, in at least some embodiments, minimize the total thickness variation of the article of semiconducting material.

Other exemplary embodiments of the disclosure relate to methods of minimizing the total thickness variation of an article of semiconducting material using a substrate mold having graded density.

### BRIEF DESCRIPTION OF DRAWINGS

The accompanying drawings are included to provide a further understanding of the invention, and are incorporated in and constitute a part of this specification. The drawings are not intended to be restrictive of the invention as claimed, but rather are provided to illustrate exemplary embodiments of the invention and, together with the description, serve to explain the principles of the invention.

FIGS. 1A-C are a schematic illustration of an exemplary method of making an article of semiconducting material according to an embodiment of the disclosure;

FIG. 2 is a graph illustrating the relationship between the residence time (in seconds) and the thickness (in microns) of a solidified silicon layer formed on a mold having uniform thermophysical properties;

FIG. 3 is a graph illustrating a relationship between the residence time (in seconds) and the thickness (in microns) of a solidified silicon layer formed on molds of varied thermal mass, where the initial substrate temperature is 400° C.;

FIG. 4 is also a graph illustrating a relationship between the residence time (in seconds) and the thickness (in microns) of a solidified silicon layer formed on molds of varied thermal mass, where the initial substrate temperature is 800° C.; and

FIG. 5 is also a graph illustrating a relationship between the residence time (in seconds) and the thickness (in microns) of a solidified silicon layer formed on molds of varied thermal mass.

### DETAILED DESCRIPTION

It is to be understood that both the foregoing general description and the following detailed description are exemplary and explanatory only and are not restrictive of the invention, as claimed. Other embodiments will be apparent to those skilled in the art from consideration of the specification and practice of the embodiments disclosed herein. It is intended that the specification and examples be considered as exemplary only, with the true scope and spirit of the invention being indicated by the claims.

As used herein the use of “the,” “a,” or “an” means “at least one,” and should not be limited to “only one” unless explicitly indicated to the contrary. Thus, for example, the use of “the semiconducting material” or “a semiconducting material” is intended to mean at least one semiconducting material.

The disclosure relates, in various embodiments, to substrate molds comprising refractory materials having a leading edge and a trailing edge, wherein the substrate mold has a variable thermal mass comprising a leading edge thermal mass (M_{t(lead)}) and a trailing edge thermal mass (Mₜ₍ₜᵣₐᵢₗ₎), wherein M_{t(lead)} is less than Mₜ₍ₜᵣₐᵢₗ₎.

As used herein, the terms “substrate mold” and “mold” are used interchangeably throughout to mean a physical structure having an external surface upon or over which an article of semiconducting material can be formed. Molten or solidified semiconducting material need not physically contact an external surface of the mold, although contact may occur.

The term “external surface” means a surface of the substrate mold that may be exposed to molten semiconducting material upon submersion of the mold into molten semiconducting material. For example, the interior surface of a tube-shaped mold may be an external surface if the interior surface can contact a molten semiconducting material when the mold is immersed.

As used herein, the term “semiconducting material” includes materials that exhibit semiconducting properties. In various embodiments, the semiconducting material may be chosen from silicon, germanium, gallium arsenide, and alloys thereof; alloys and compounds of tin; and mixtures thereof. In at least one embodiment, the semiconducting material may be silicon. According to various embodiments, the semiconducting material may be pure (such as, for example, intrinsic or i-type silicon) or doped (such as, for example, silicon containing a n-type or p-type dopant, such as phosphorous or boron, respectively). In various embodiments, the semiconducting material may be chosen from a mixture of two or more materials, such as, for example, silicon carbide and fused silica powders.

In at least one embodiment of the disclosure, the semiconducting material comprises at least one dopant chosen from boron, phosphorous, or aluminum (B, P, or Al). The amount of dopant present in the molten semiconducting material may be chosen based on the desired dopant concentration in the produced article of semiconducting material, and may depend on the final intended use of the article, such as, for example, a photovoltaic cell. According to at least one embodiment, an article of semiconducting material may comprise a dopant dispersed substantially evenly throughout the semiconducting material (e.g., without substantial segregation of the dopant within the semiconducting material).

In at least one further embodiment, the semiconducting material may comprise at least one non-semiconducting element that may form a semiconducting alloy or compound with another element. For example, the semiconducting material may be chosen from gallium arsenide (GaAs), aluminum nitride (AlN), and/or indium phosphide (InP).

In at least one embodiment, the semiconducting material may have low contaminant levels. For example, the semiconducting material may comprise less than 1 ppm of iron, manganese, and chromium, and/or less than 1 ppb of vanadium, titanium, and zirconium. The semiconducting material may also comprise less than 10¹⁵ atoms/cm³ of nitrogen and/or less than 10¹⁷ atoms/cm³ of carbon. In at least one embodiment, the source of the semiconducting material may be photovoltaic-grade, or purer, silicon.

In at least one embodiment, the substrate mold may be formed from a material that is compatible with the molten semiconducting material. For example, the mold may optionally be formed from a refractory material that does not melt or soften when submersed in the molten semiconducting material. As a further example, the mold may be thermally stable and/or chemically inert to the molten semiconducting material and, therefore, non-reactive or substantially non-reactive with the molten semiconducting material.

In various embodiments, the mold may comprise refractory materials such as fused silica, graphite, silicon nitride, single crystal or polycrystalline silicon, as well as combinations and composites thereof. In at least one embodiment, the mold may be made of vitreous silicon dioxide or quartz. The mold may optionally have a thickness ranging from about 0.1 mm to about 100 mm (e.g., about 0.1, 0.2, 0.5, 1, 2, 5, 10, 20, 50 or 100 mm). A length and width of the mold may optionally vary, independently, from about 1 cm to about 100 cm, or greater.

The mold of the disclosure has a leading edge and a trailing edge separated by a length. In at least one embodiment, the length may be oriented substantially parallel to the direction in which the mold is intended to be submersed in molten semiconducting material, such that the leading edge would therefore be submersed for a time greater than the trailing edge. The leading edge and trailing edge may be at the end points of the mold length, at a point along the mold length, or a combination thereof. For example, in at least one embodiment, the leading edge may be at the outermost portion of the mold that is submersed first, i.e., at time zero, and/or the trailing edge may be at the opposite outer most portion of the mold length, i.e., the portion that is submersed last. In another embodiment, the leading edge or trailing edge may be located at the center-point of the mold length or another point along the length.

In various embodiments, the substrate mold may have a variable or “graded” thermal mass over its length. The graded thermal mass comprises a leading edge thermal mass (M_{t(lead)}) and a trailing edge thermal mass (Mₜ₍ₜᵣₐᵢₗ₎), wherein M_{t(lead)} is less than Mₜ₍ₜᵣₐᵢₗ₎. The leading edge thermal mass and trailing edge thermal mass are the thermal masses of the substrate mold material at the leading edge and trailing edge, respectively.

The desired extent and manner of gradation in the thermal mass of the substrate mold, i.e., the difference in M_{t(lead)} and Mₜ₍ₜᵣₐᵢₗ₎, may be determined by those of skill in the art, depending, for example, on the intended properties and/or use of the article of semiconducting material. For example, the desired extent and manner of gradation may be achieved by varying the thermal mass of the mold material step-wise, i.e., having one or more distinct changes in thermal mass; by a substantially continuous variation in thermal mass, such as a linear or exponential change across the length of the substrate; or any combination thereof. In at least one embodiment, the graded thermal mass may comprise at least one step-wise gradation from M_{t(lead)} to Mₜ₍ₜᵣₐᵢₗ₎. In a further embodiment, the graded density may be a substantially linear gradation from M_{t(lead)} to Mₜ₍ₜᵣₐᵢₗ₎.

The gradation in thermal mass of the mold may be achieved by any method known to those of skill in the art. For example, the thermal mass may be varied by varying the porosity of the substrate mold material, varying the material composition of the substrate mold, or a combination thereof.

For example, in one embodiment, the porosity of the substrate mold may be varied by changing the particle size or porosity of the mold material, such as by switching from high purity fused silica glass particles, i.e. changing the porosity from about 40% down to about 0%. The porosity of the substrate mold may include, for example, about 40%, such as about 35%, about 30%, about 25%, about 20%, about 15%, about 10%, about 8%, about 5%, about 3%, about 2%, or about 1%.

In another embodiment, the material composition of the substrate mold may be changed by transitioning from lighter to heavier material, using materials such as vitreous or dissolved silica, such as, for example boron oxide, phosphorus oxide, or aluminum oxide additives; silicon; other silica compounds, for example silica nitride or carbide powders; mixtures of silica with other oxides; and/or ceramic alloys.

In various exemplary embodiments, the difference in M_{t(lead)} and Mₜ₍ₜᵣₐᵢₗ₎ may be about 1% or greater, such as about 2% or greater, about 5% or greater, about 10% or greater, about 15% or greater. In one exemplary embodiment, the difference in M_{t(lead)} and Mₜ₍ₜᵣₐᵢₗ₎ is about 20%.

In various embodiments, the mold may comprise a uniform or non-uniform composition, uniform or non-uniform porosity, or other uniform or non-uniform structural characteristic in any direction. This may include, for example, a length oriented substantially parallel to the direction in which the mold is intended to be submersed, as well as the mold thickness and/or width. For example, in at least one embodiment, the core of the mold and the external surface of the mold may be comprised of different materials and have different thermal masses. In another embodiment, the mold may have substantially uniform thermal mass in thickness and/or across its width, i.e., substantially perpendicular to the direction in which the mold is submersed in molten semiconducting material

The mold may be in any form suitable for use in the disclosed methods. For example, in at least one embodiment, the mold may be in the form of a monolith or in the form of a laminated structure, such as, for example, a laminated monolith.

According to at least one embodiment, the mold may also be in any shape suitable for use in the disclosed methods. In at least one embodiment, the mold may have an external surface with particular characteristics to form articles having a broad range of shapes, curvatures, and/or textures. For example, the mold may comprise one or more flat surfaces or one or more curved surfaces, for example one or more convex or concave surfaces. For example, the one or more flat surfaces may be used to create an article in the shape of a rectangle, and the one or more convex or concave surfaces may be used to create an article in the shape of a lens or a tube.

In other exemplary embodiments, the disclosure relates to methods of making an article of semiconducting material using molds having a graded thermal mass, as described herein. Methods contemplated include, for example, exocasting methods whereby an article of a semiconducting material is formed over a surface of a substrate mold having graded thermal mass. In at least one embodiment, the disclosure relates to methods of making an article of semiconducting material comprising: providing a substrate mold with a graded thermal mass as described herein; immersing the substrate mold in molten semiconducting material for a period of time sufficient to form a solid layer of the semiconducting material over an external surface of the mold; withdrawing the mold with a solid layer of semiconducting material thereon from the molten semiconducting material to form an article of semiconducting material. Optionally, the methods may further include a step of separating the solid layer of semiconducting material from the substrate mold to form an unsupported article of semiconducting material.

As used herein, the phrase “article of semiconducting material” includes any shape or form of semiconducting material made using the methods of the disclosure. Examples of such articles include articles that are smooth or textured; articles that are flat, curved, bent, or angled; and articles that are symmetric or asymmetric. Articles of semiconducting materials may comprise forms such as sheets or tubes.

As used herein, the term “unsupported” means that an article of semiconducting material is not integral with a mold. The unsupported article may be loosely connected to the mold while it is being formed, but the article of semiconducting material is separated from the mold after it is formed over the mold. The unsupported article may, however, be subsequently applied on a substrate for various applications, such as photovoltaic applications. In at least one embodiment, the article of semiconducting material is unsupported.

As used herein, the phrase “form a solid layer of semiconducting material over an external surface of the mold” and variations thereof mean that semiconducting material from the molten semiconducting material solidifies (also referred to as freezing or crystallizing) on or near an external surface of the mold. In various embodiments, due to the temperature difference between the mold and the molten semiconducting material, the semiconducting material may solidify before it physically contacts the surface of the mold. When the semiconducting material solidifies before it physically contacts the mold, the solidified semiconducting material may, in some embodiments, subsequently come into physical contact with the mold. The semiconducting material may, in some embodiments, also solidify after physically contacting the external surface of the mold.

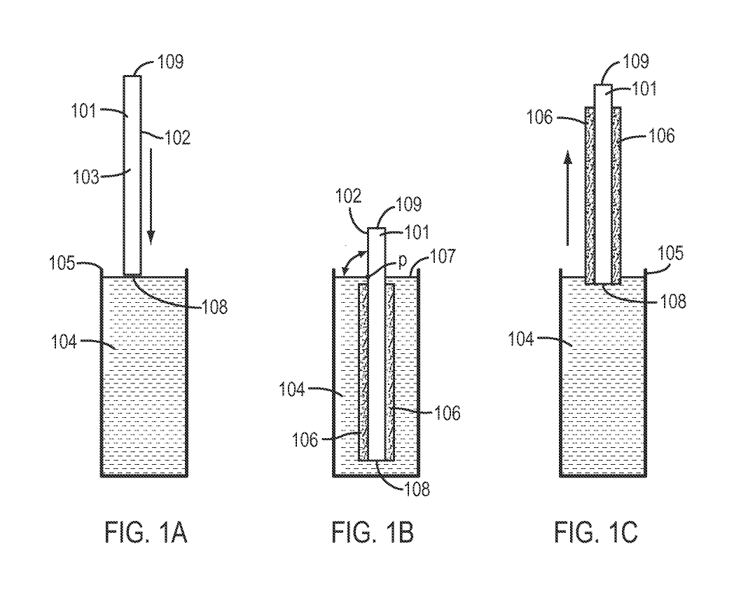

FIG. 1 illustrates one exemplary method of making an article of a semiconducting material according to the disclosure. The exemplary method is an exocasting process, in which the article is cast on a surface, such as an external surface, of a substrate mold, rather than only filling a mold cavity. In the exemplary method shown in FIG. 1A, the mold 101 is provided having an external surface 102 with a desired size (surface area), shape, and surface texture/pattern, a core 103, and a graded thermal mass wherein M_{t(lead)} at leading edge 108 is less than Mₜ₍ₜᵣₐᵢₗ₎ at trailing edge 109. The surface area, shape, and surface texture/pattern of the external surface 102 of the mold 101 may determine the size, shape, and surface texture/pattern of the cast article. One of ordinary skill in the art would recognize that the size, shape, and surface texture/pattern of the external surface 102 of the mold 101 can be selected based on, for example, the desired properties and features of the cast article.

Molten semiconducting material 104 such as, for example, molten silicon, may in at least one embodiment be provided by melting silicon in a vessel 105, such as a crucible. In at least one embodiment the vessel 105, which holds the molten semiconducting material 104, may not react with the molten material 104 and/or may not contaminate the molten material 104, as described above for the mold 101. In at least one embodiment, the vessel 105 may be made from materials chosen from one or more of vitreous silica, graphite, and silicon nitride. In at least one embodiment, vessel 105 is made of vitreous silica.

As shown in the exemplary embodiment of FIG. 1B, the mold 101 may be immersed in the molten semiconducting material 104 at a desired rate, with the leading edge 108 entering before the trailing edge 109, and optionally in a low oxygen or reducing atmosphere. The mold 101 may be immersed in the molten semiconducting material 104 in any direction, such as, for example, a direction that is substantially parallel to a length of the mold, as seen in FIG. 1B. In further exemplary embodiments, the mold 101 may be immersed at an angle θ, such as, for example, an angle θ that is acute or obtuse to a direction that is substantially parallel to a length of the mold. The angle θ is the angle between the surface 107 of molten semiconducting material 104 and an external surface 102 of the mold 101 at the point p, which is the point where the solid mold is in contact with the air and the surface 107 of molten semiconducting material 104, as shown in FIG. 1B.

In various embodiments, immersion of the mold may be accomplished using any suitable technique, and may be accomplished by immersing the mold from above the molten semiconducting material or from the side or bottom of the molten semiconducting material.

When a mold having a temperature less than that of the molten semiconducting material is dipped into the melt, the liquid adjacent to the mold starts to solidify and the average solidification front initially moves into the melt in a direction substantially perpendicular to the surface of the mold. If the mold is dipped for long enough time, when the heat sink provided by the mold is depleted, the solidified semiconducting layer 106 starts to remelt at the surface contacting the melt. The mold may then be removed from the melt after a predetermined time corresponding to the desired thickness of the layer of semiconducting material.

In at least one embodiment, the mold 101 may be immersed in the molten semiconducting material 104 for a period of time sufficient to allow a layer 106 of the semiconducting material to sufficiently solidify on a surface 102 of the mold 101. In at least one embodiment, the semiconducting material is sufficiently solidified when enough semiconducting material has solidified such that the mold can be withdrawn from the molten semiconducting material and the layer of semiconducting material 106 will be withdrawn with the mold. By way of example only, the mold 101 may be immersed in the molten semiconducting material 104 for up to 30 seconds. In a further embodiment, the mold 101 may be immersed from about 0.5 seconds to about 30 seconds. By way of example, the mold 101 may be immersed in the molten semiconducting material 104 for about 1 second to about 10 seconds. In another exemplary embodiment, the mold 101 may be immersed in the molten semiconducting material 104 for greater than 30 seconds. The immersion time may be varied appropriately based on parameters known to those of skill in the art, such as, for example, the thickness of the mold, the temperatures and heat transfer properties of the mold and the molten semiconducting material, and the desired thickness of the formed article of semiconducting material. Thus, the appropriate immersion time could easily be determined by one skilled in the art.

Due to the vertical nature of the dip process, different locations along the vertical length of the substrate mold experience different residence time in the liquid due to finite dip and pull out rates. The leading edge of the substrate is in contact with the melt for a longer time than the trailing edge. This leads to an excess residence time for the leading edge equal to L/V_{dip}+L/Vₚᵤₗₗ, where L is the length between the leading edge and trailing edge of the substrate and V_{dip} and Vₚᵤₗₗ are the dip and pull velocities, respectively. Because the excess residence time may be proportional to the length of the substrate, particularly when the leading and trailing edges are at the mold endpoints, the larger the sample, the larger the variation in residence time may be between the leading and trailing edges.

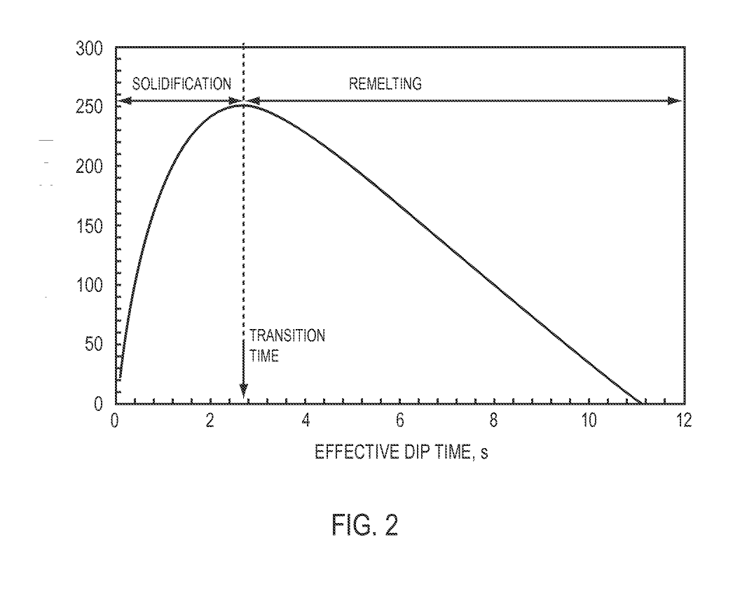

The thickness of the solidified layer of semiconducting material may be a function of dip time, and the variation of residence time between the leading edge and trailing edge could lead to large variability of thickness of the solidified layer. FIG. 2 is a graph illustrating the relationship between the residence time (in seconds) and the thickness (in microns) of a solidified silicon layer formed on a mold having uniform thermophysical properties.

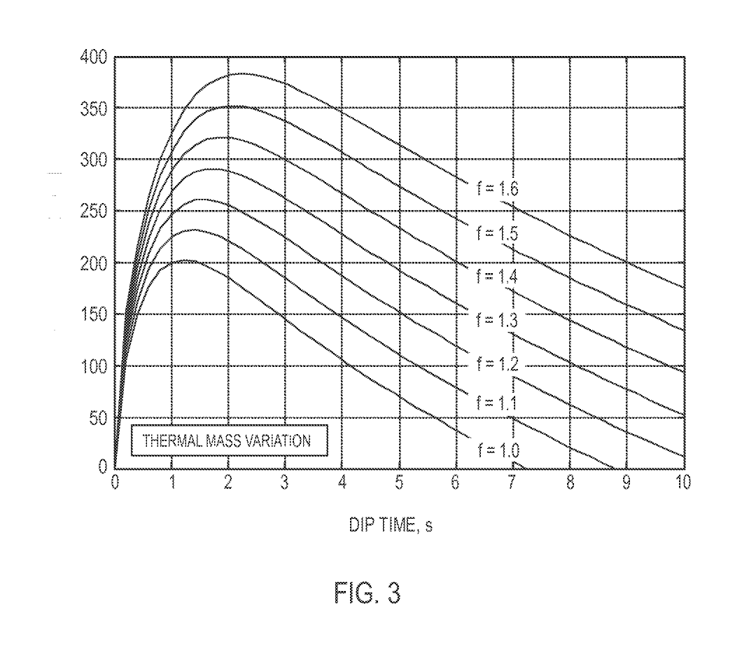

In order to obtain semiconducting articles with minimal total thickness variation, local properties of the mold, such as the thermophysical properties of the mold as described herein, may be varied to compensate for residence time variation. For example, looking at FIGS. 3-5, it can be seen that a difference in thermal mass of the mold can lead to different thicknesses of the solid layer of semiconducting material formed, when the mold is immersed for the same amount of time. The final thickness of the solid layer of semiconducting material may be, for example, up to about 600 μm, such as, for example about 50 μm to about 500 μm, or about 100 μm to about 400 μm. In FIGS. 3-5, the variable f represents the relative thermal mass to silica. In embodiments, the thermal mass gradient within the mold can be affected by changing one or more of porosity, density and heat capacity.

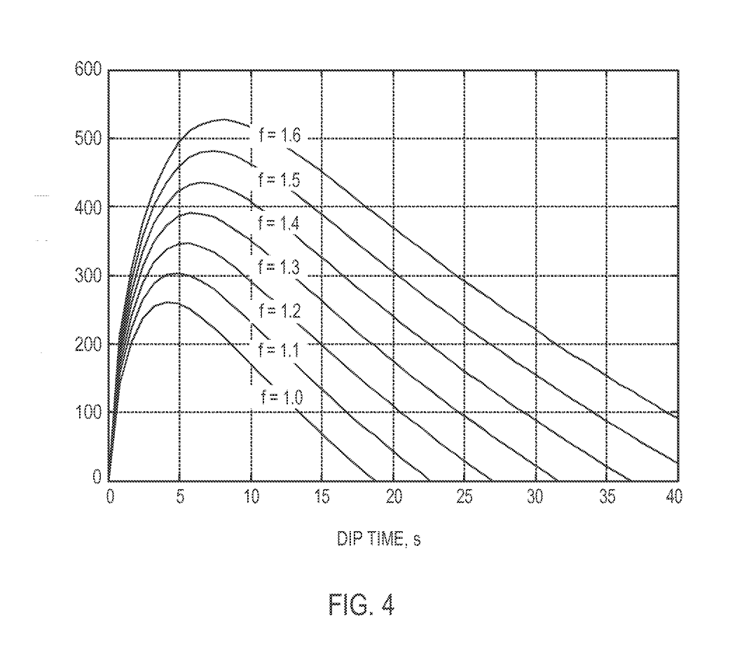

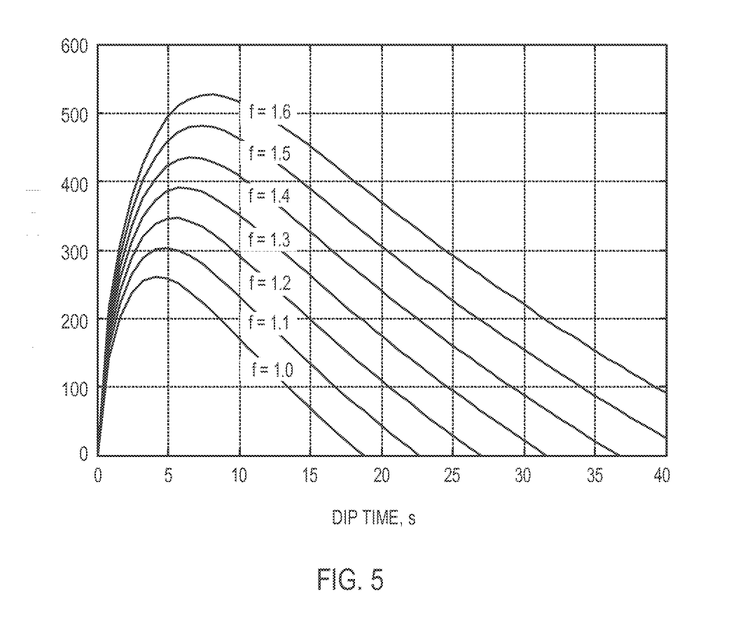

FIG. 3 is a graph illustrating the relationship between the residence time (in seconds) and the thickness (in microns) of a solidified silicon layer formed on molds of varied thermal mass, ranging from 2.2 g/cm³ to 3.5 g/cm³, where the initial substrate temperature is 400° C. FIG. 4 is also a graph illustrating the relationship between the residence time (in seconds) and the thickness (in microns) of a solidified silicon layer formed on molds of varied densities, ranging from 2.2 g/cm³ to 3.5 g/cm³, where the initial substrate temperature is 800° C. As depicted in FIG. 5, two different densities, such as, for example, 2.2 g/cm3 and 3.5 g/cm³, may produce solidified silicon layers of the same thickness, such as 200 microns, at different residence times, such as about 8 seconds and about 12 seconds respectively. Thus, substrate molds having variable or graded thermal mass, as described herein, may achieve minimal thickness variation despite varied residence time during exocasting.

Returning to FIG. 1C, after submersion, the mold 101 with a layer of semiconducting material 106 may be withdrawn from the molten semiconducting material 104. In at least one embodiment, the mold 101 with a layer of semiconducting material 106 may be cooled after it is removed from the molten semiconducting material 104, either actively such as by convective cooling, or by allowing the temperature of the layer of semiconducting material 106 to come to room temperature.

After the mold is removed from the molten semiconducting material and sufficiently cooled, the solid layer of semiconducting material may optionally be removed or separated from the mold, by any method known to those of skill in the art.

In various embodiments, a number of additional process parameters may also be varied, including but not limited to: (1) the external surface temperature of the mold at which it is provided prior to immersion in the molten semiconducting material; (2) the rate at which mold is submersed into the molten semiconducting material; (3) the length of time that the mold is submersed in the molten semiconducting material; (4) the rate at which mold having the layer of semiconducting material is removed from the molten material; and (5) cooling of the solidified semiconducting material.

According to at least one embodiment, the rate at which the mold is immersed into the molten semiconducting material may range from about 1.0 cm/s to about 50 cm/s, such as, for example, from about 3 cm/s to about 10 cm/s. One skilled in the art would recognize that the immersion rate may vary depending on various parameters, such as, for example, the semiconducting material composition (including optional dopants), the size/shape of the mold, and the surface texture of the mold.

According to various embodiments, the rate at which the mold is removed from the molten semiconducting material may range from about 0.2 cm/s to about 50 cm/s, such as about 0.2 cm/s to about 40 cm/s, about 0.2 cm/s to about 30 cm/s, about 0.5 cm/s to about 20 cm/s, or about 0.5 cm/s to about 10 cm/s. In at least one embodiment, the rate at which the mold is removed from the molten semiconducting material is about 0.5 cm/s to about 5 cm/s.

Other exemplary embodiments of the disclosure relate to methods of minimizing the total thickness variation from the leading edge to the trailing edge of an article of semiconducting material using a substrate mold having graded density.

As used herein, the phrase “minimizing the total thickness variation,” and variations thereof, is intended to include reducing the total thickness variation from the leading edge to the trailing edge of the solidified semiconducting layer achieved by methods disclosed herein, relative to methods not within the scope of the disclosure. In various embodiments, the total thickness variation from edge to edge may be about 20% or less. By way of example, the total thickness variation from edge to edge may be about 15% or less, such as about 12% or less, about 10% or less, about 8% or less, about 5% or less, about 3% or less, about 2.5% or less, about 2% or less, or about 1.5% or less.

The methods according to the disclosure may also, in at least some embodiments, yield articles of semiconducting material having a reduced material waste.

As used herein, the phrase “reduced material waste” and variations thereof mean any reduction in the amount of semiconducting material lost through conventional methods.

Unless otherwise indicated, all numbers used in the specification and claims are to be understood as being modified in all instances by the term “about,” whether or not so stated. It should also be understood that the precise numerical values used in the specification and claims form additional embodiments of the invention, and are intended to include any ranges which can be narrowed to any two end points disclosed within the exemplary values provided. Efforts have been made to ensure the accuracy of the numerical values disclosed herein. Any measured numerical value, however, can inherently contain certain errors resulting from the standard deviation found in its respective measuring technique.

What is claimed:

1. A substrate mold, comprising:
a refractory material and having a leading edge and a trailing edge;
wherein the refractory material comprising the substrate mold has a variable thermal mass comprising a leading edge thermal mass (M_{t(lead)}) and a trailing edge thermal mass (Mₜ₍ₜᵣₐᵢₗ₎) such that M_{t(lead)} is less than Mₜ₍ₜᵣₐᵢₗ₎.

2. The substrate mold of claim 1, wherein the variable thermal mass varies continuously from M_{t(lead)} to Mₜ₍ₜᵣₐᵢₗ₎.

3. The substrate mold of claim 1, wherein the variable thermal mass comprises at least one step-wise gradation from M_{t(lead)} to Mₜ₍ₜᵣₐᵢₗ₎.

4. The substrate mold of claim 1, wherein the variable thermal mass is achieved at least in part by variation of the porosity of the substrate mold.

5. The substrate mold of claim 1, wherein the substrate mold is comprised of at least two refractory materials, and the variable thermal mass is achieved at least in part by variation in the material composition of the substrate mold.

6. A method of making an article of a semiconducting material, said method comprising:
providing a substrate mold with a variable thermal mass from the leading edge to the trailing edge;
immersing the substrate mold in molten semiconducting material for a period of time sufficient to form a solid layer of the semiconducting material over an external surface of the mold; and
withdrawing the mold with the solid layer of semiconducting material from the molten semiconducting material;
wherein the variable thermal mass of the substrate mold comprises a leading edge thermal mass (M_{t(lead)}) and a trailing edge thermal mass (Mₜ₍ₜᵣₐᵢₗ₎), and M_{t(lead)} is less than Mₜ₍ₜᵣₐᵢₗ₎.

7. The method of claim 6, wherein the semiconducting material is chosen from silicon, alloys and compounds of silicon, germanium, alloys and compounds of germanium, gallium arsenide, alloys and compounds of gallium arsenide, alloys and compounds of tin, and mixtures thereof.

8. The method of claim 6, wherein the semiconducting material is chosen from silicon, silicon alloys, and silicon compounds.

9. The method of claim 6, wherein the solid layer of semiconducting material has a thickness ranging from 100 μm to 400 μm.

10. The method of claim 6, wherein the solid layer of semiconducting material has a total thickness variation of less than 20%.

11. The method of claim 6, wherein the solid layer of semiconducting material has a total thickness variation of less than 10%.

12. The method of claim 6, further comprising a step of separating the solid layer of semiconducting material from the substrate mold to form an unsupported article of semiconducting material.

13. A method of minimizing the total thickness variation of an unsupported article of semiconducting material, comprising:
providing a substrate mold with a variable thermal mass;
immersing the substrate mold in molten semiconducting material for a period of time sufficient to form a solid layer of the semiconducting material over an external surface of the mold;
withdrawing the mold with the solid layer of semiconducting material from the molten semiconducting material; and
separating the solid layer of semiconducting material from the substrate mold to form the unsupported article of semiconducting material;
wherein the variable thermal mass of the substrate mold comprises a leading edge thermal mass (M_{t(lead)}) and a trailing edge thermal mass (Mₜ₍ₜᵣₐᵢₗ₎), and
wherein M_{t(lead)} is less than Mₜ₍ₜᵣₐᵢₗ₎.

14. The method of claim 13, wherein the solid layer of semiconducting material has a total thickness variation of less than 20%.

15. The method of claim 13, wherein the solid layer of semiconducting material has a total thickness variation of less than 10%.

16. The method of claim 13, wherein the semiconducting material is chosen from silicon, silicon alloys, and silicon compounds.

17. The method of claim 13, wherein the solid layer of semiconducting material has a thickness ranging from 100 μm to 400 μm.
